(19) United States
(12) Patent Application Publication
(10) Pub. No.: US 2020/0350409 A1
(43) Pub. Date: Nov. 5, 2020

(54) Growth of Single Atom Chains for Nano-Electronics and Quantum Circuits

(71) Applicant: BOARD OF TRUSTEES OF THE UNIVERSITY OF ARKANSAS, Little Rock, AR (US)

(72) Inventors: Shui-Qing Yu, Fayetteville, AR (US); Hugh Churchill, Fayetteville, AR (US); Gregory J. Salamo, Fayetteville, AR (US)

(73) Assignee: BOARD OF TRUSTEES OF THE UNIVERSITY OF ARKANSAS, Little Rock, AR (US)

(21) Appl. No.: 16/931,246

(22) Filed: Jul. 16, 2020

Related U.S. Application Data
(62) Division of application No. 15/910,789, filed on Mar. 2, 2018.
(60) Provisional application No. 62/466,074, filed on Mar. 2, 2017.

(51) Int. Cl. H01L 29/18; C30B 29/02; C30B 23/02; H01L 21/02; H01L 31/0272; B82Y 10/00; H01L 29/06; H01L 29/66; C30B 29/60; H01L 31/108

(52) U.S. Cl. CPC H01L 29/18; H01L 39/12; C30B 23/02; H01L 21/02521; H01L 21/02631; H01L 21/02395; H01L 21/0242; H01L 31/0272; H01L 21/0243; H01L 21/02603; B82Y 10/00; H01L 29/0673; H01L 29/66977; H01L 29/66984; C30B 29/60; H01L 31/108; C30B 29/02

(57) ABSTRACT

A semiconductor device made of one or more one-dimensional chains of atoms. The atoms form covalent bonds along the chain with no dangling bonds except at both ends of the chain.

### RELATED APPLICATIONS

This application is a divisional of U.S. application Ser. No. 15/910,789 filed on Mar. 2, 2018, which claims the benefit of U.S. Provisional Application No. 62/466,074 filed Mar. 2, 2017, both of which are herein incorporated by reference.

### STATEMENT REGARDING FEDERALLY SPONSORED RESEARCH & DEVELOPMENT

Not applicable.

### INCORPORATION BY REFERENCE OF MATERIAL SUBMITTED ON A COMPACT DISC

Not applicable.

### BACKGROUND OF THE INVENTION

The discovery of a single sheet of carbon atoms has led to the development of two-dimensional (2D) materials beyond graphene, which show superior electrical, optical, mechanical, and chemical properties and therefore has the potential to revolutionize electronics. What is characteristic of 2D materials is that they are composed of layers of atoms that form strong covalent bonds within each layer without dangling bonds. Meanwhile, the interlayer bonding is solely due to the van der Waals force, which is much weaker than the covalent bond so that an individual 2D layer of atoms could be easily separated.

Thus, many elemental chains (EC) such as Se, Al, Ba, Bi, Sb, and Sr have been theoretically studied for the band structure, and it is predicted that some of them might exist under extreme conditions, such as high pressure. The success of STM development has enabled the manipulation of single atoms to form ordered linear or 2D arrays. This has triggered theoretical investigations using artificially formed 1D atomic chains to build electronic devices, which are seen as the ultimate building blocks for transistors.

### BRIEF SUMMARY OF THE INVENTION

In one embodiment, the present invention provides a method that enables a full suite of “atom circuits and devices” based on switching electron waves between atom chains as shown in FIG. 1.

In other embodiments, the present invention provides methods that create chains of atoms.

In other embodiments, the present invention provides methods that create isolated single chains or multiple chains that are controllably coupled to each other.

In other embodiments, the chains may be one-dimensional chains of atoms, the atoms form strong covalent bonds with no dangling bonds except at both ends of the chain and the chains are bonded together through van der Waals force.

In other embodiments, the present invention provides methods that create chains of atoms to form regular integrated circuits or quantum integrated circuits.

In other embodiments, the chains host quantum dots functioning as single photon sources and detectors and as electron spin qubits.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

In the drawings, which are not necessarily drawn to scale, like numerals may describe substantially similar components throughout the several views. Like numerals having different letter suffixes may represent different instances of substantially similar components. The drawings illustrate generally, by way of example, but not by way of limitation, a detailed description of certain embodiments discussed in the present document.

FIG. 1 illustrates atom circuits and devices such as a switching electrode that may be created using the embodiments of the present invention.

FIG. 2A is a schematic of a Se single crystal formed by single atom chains bonded by van der Waals force.

FIG. 2B calculates Se atom chain band structure showing a direct bandgap of 1.95 eV for the schematic of FIG. 2A.

FIG. 3A is an optical image of a Se single crystal.

FIG. 3B is a schematic of graphene exfoliation process that may be used with an embodiment of the present invention.

FIG. 3C is a schematic of an atomic chain exfoliation process that may be used with an embodiment of the present invention.

FIG. 4A shows steps on a high index surface as a template for atom chains that may be used with an embodiment of the present invention.

FIG. 4B is a schematic of self-organized chains on the steps for an embodiment of the present invention.

FIG. 5A illustrates a SeTe chain heterostructure for an embodiment of the present invention.

FIG. 5B illustrates a Se chain branch structure connected with an impurity atom for an embodiment of the present invention.

FIG. 5C illustrates forming ring structure using chain for an embodiment of the present invention.

FIGS. 6A and 6B are a list of basic building blocks for quantum circuits and their layouts and transfer functions.

### DETAILED DESCRIPTION OF THE INVENTION

Detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a representative basis for teaching one skilled in the art to variously employ the present invention in virtually any appropriately detailed method, structure or system. Further, the terms and phrases used herein are not intended to be limiting, but rather to provide an understandable description of the invention.

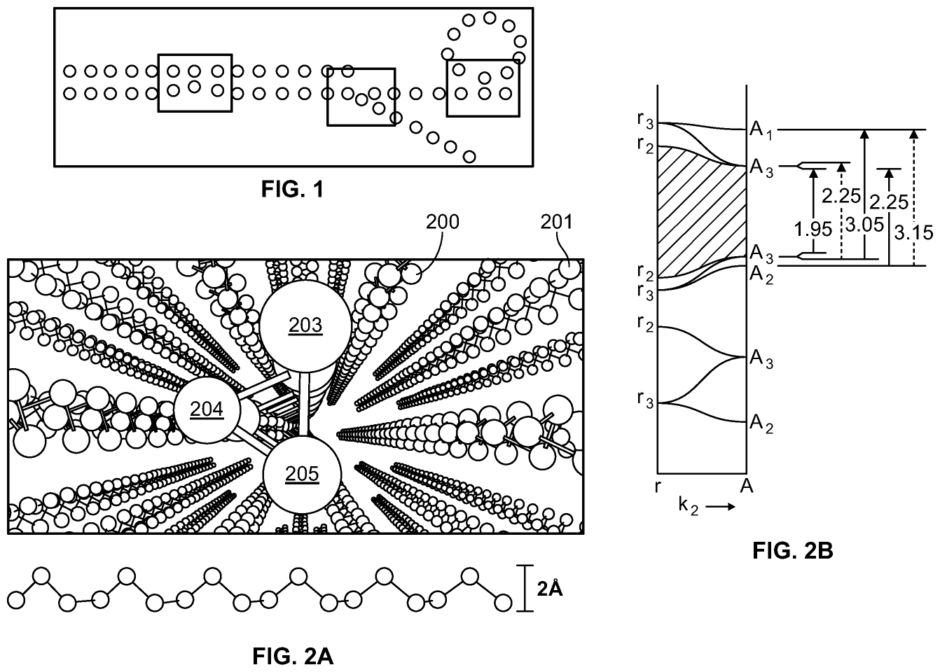

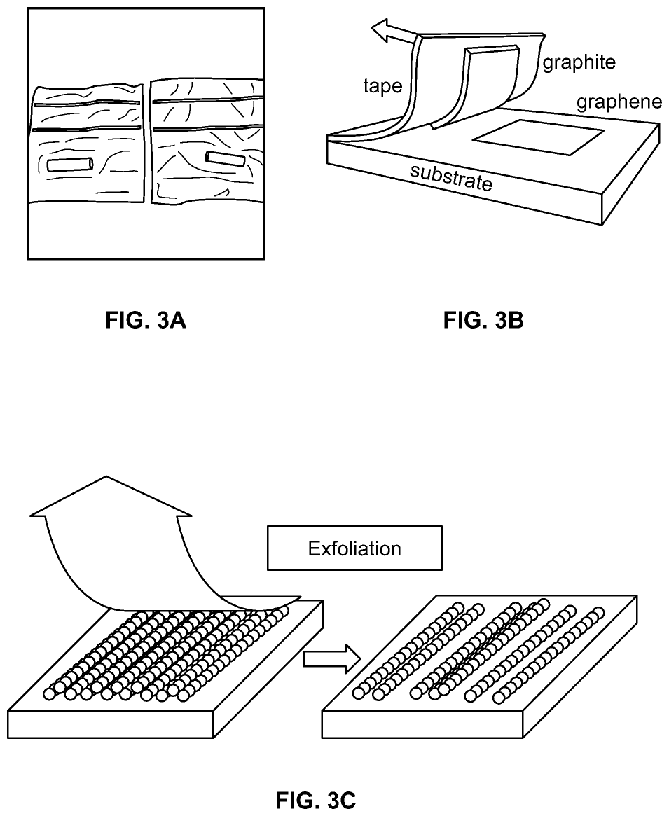

One element that may be formed into elemental chains (EC) is Si which has semiconductor properties as shown in FIG. 1. For example, Si is a metallic (EC). On the other hand, as shown in FIGS. 2A and 2B, crystalline Se and Te have a lattice consisting of spiral chains 200-201 oriented along the c-axis, each spiral having three atoms 203-205 per turn with equivalent atoms on adjacent chains forming a hexagonal plane network of atoms. Nearest neighbors lie on the same chain, and second-nearest neighbors lie in adjacent chains. Se and Te belong to group-VI elements, and each atom's outer shell has two empty states so that it could form two covalent bonds. In the crystal structure, each atom forms two covalent bonds with the nearest neighbor atoms within the atom chain and no additional dangling bonds.

The interchain bonding (van der Waals) is much weaker than the intrachain bonding (covalent). This weak bonding may be utilized in the very early stage of van der Waals epitaxy to grow Se on Te to achieve a high-quality large lattice mismatch growth.

Accordingly, for a preferred embodiment of the present invention, 1D elemental chain materials may be formed, including single Se and Te atomic chains, as well as heterostructures formed by them. These structures may be used as basic building blocks to construct nano-electronics and quantum circuits.

To obtain single atomic chains of Se and Te, two approaches may be used. A top-down approach may be used to separate a single sheet of material such as graphene to separate single atomic chains. A bottom-up approach may also be used to perform self-assembly of atomic chain growth on high-index crystal substrates.

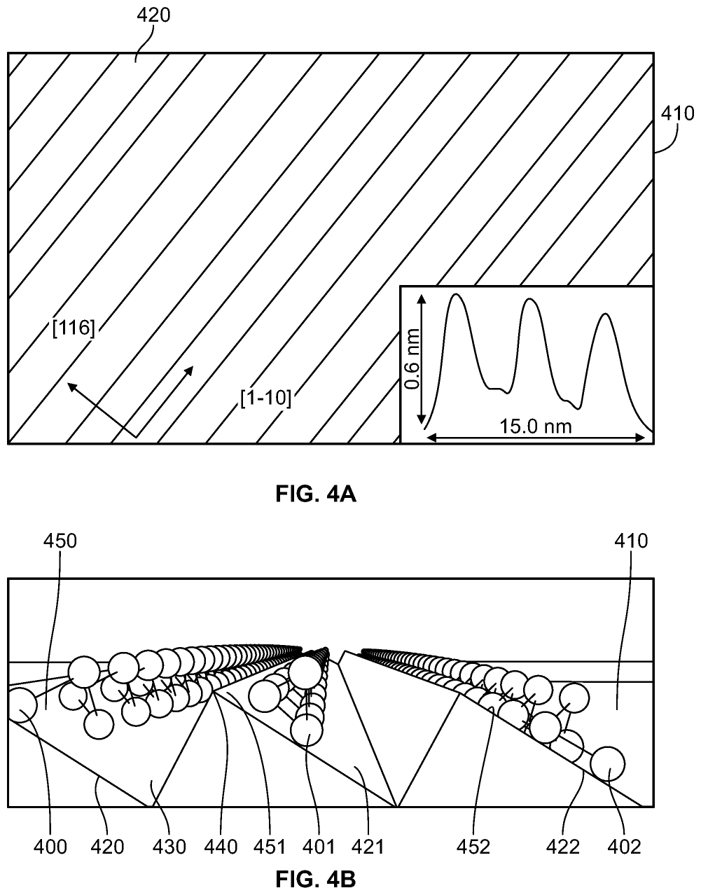

FIGS. 3A and 3B show a comparison of the difference of the exfoliation process for graphene (2D material) and single atomic-chains (1D material). Instead of getting sheets of layered structures, exfoliation for 1D materials leave materials with random heights, long “line defects”, and occasionally, isolated chains.

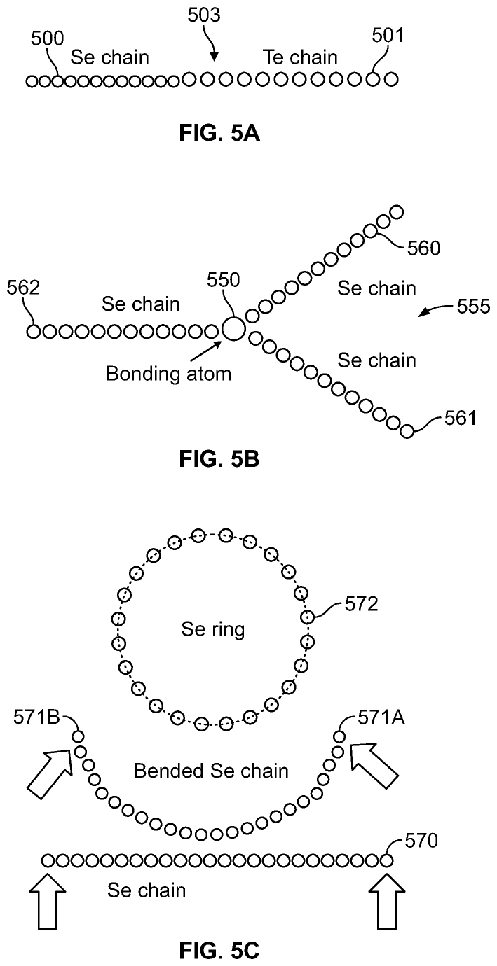

When Se atoms are forced to align in 1D, they tend to spontaneously form an atomic chain with two neighbor atoms connected with a covalent bond. Such a structure is thermodynamically stable. Based on this mechanism, the present invention, for a preferred embodiment, uses molecular beam epitaxy (MBE) to grow large area atomic chains 400-402, which may be comprised of Se and/or Te, on a high index semiconductor substrate 410 as shown in FIGS. 4A-4B. Substrate 410 includes a plurality of steps 420-422. FIG. 4C shows an engineered high index GaAs grown with MBE.

The steps of the substrate provide a natural template to guide the alignment of the atoms. The chains will form along valleys as it will take much more energy to form the bond laterally across the valleys 430-432 and peaks 440-442.

The atoms collect at terrace edges 450-452 to lower the surface energy. Therefore, stable, well-aligned, and long atomic chains could be formed. The spacing between the steps will be tuned by growing on different high index or cut substrates. MBE growth is used as it provides atomic layer resolution deposition capability, in-situ monitoring (RHEED), UHV environment, and additional control to form high index surfaces.

In other embodiments of the present invention, both Se and Te chains may be grown. Se is more anisotropic (1D-like) than Te, but Se has a much lower melting point than Te which may limit the mobility of Se atoms on growth substrates. Other embodiments may grow chains on a variety of different substrates, from high-index, reconstructed GaAs surfaces to miscut quartz and sapphire.

In other aspects, the present invention may be used to construct simple devices. One such device is a single atomic chain MOSFET. The atomic chain may be transferred to a SiO2 substrate followed by depositing dielectric material and metal contact to form a simple MOSFET. This will provide a baseline for the device characteristics. Other embodiments may also directly grow the atomic chain on miscut quartz wafers to develop in-situ fully depleted MOSFET architecture (similar to SOI).

A single chain with two electrodes will also work as optoelectronic devices such as photoconductors and diodes. By choosing different metals, the structure may also work as a Schottky diode for photodetection. An external electric field may be used to form a PN junction along the chain so that the structure could be configured as a light emitting diode. A bipolar injection may be obtained by directly engineering the metal work functions rather than using doping.

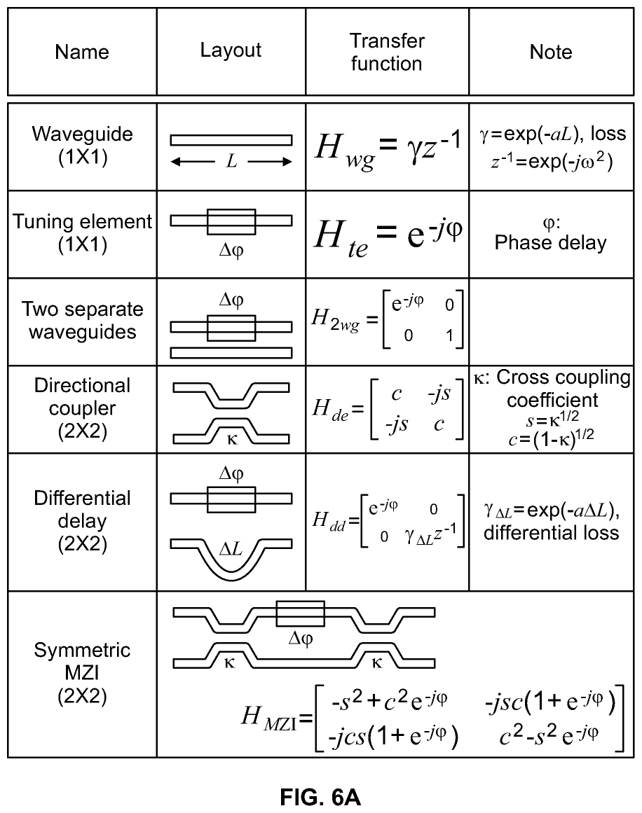

As shown in FIGS. 5A-5C, random or heterostructure chain structures may be assembled. MBE may be used to grow random alloy SeTe alloy chains or Se chains 500 and Te chains 501. These chains may be connected to form SeTe chain heterostructures 503 as shown in FIG. 5A.

As shown in FIG. 5B a branch structure may be built. By understanding the role of one or more impurity atoms 550 in the chain 555, it is possible to engineer the chain structure 555 to introduce an impurity atom 550 (for example, with three outer shell atoms) and then connect multiple chains 560-562 to atom 550 as shown in FIG. 5B.

As shown in FIG. 5C a ring structure may also be created. For this embodiment, chain 570 is bent until ends 571A, and 571B connect at which point ring 572 is formed. The radius of the ring may be controlled by controlling the number of atoms used. All structures described above, except the random chain structure, may be created using atomic-level manipulation.

In yet other embodiments, a “quantum wire” may be created by using high index quartz wafers along with the single chain structure described above. The single chain structure is an ideal platform for creating single photon emitters and single photon detectors.

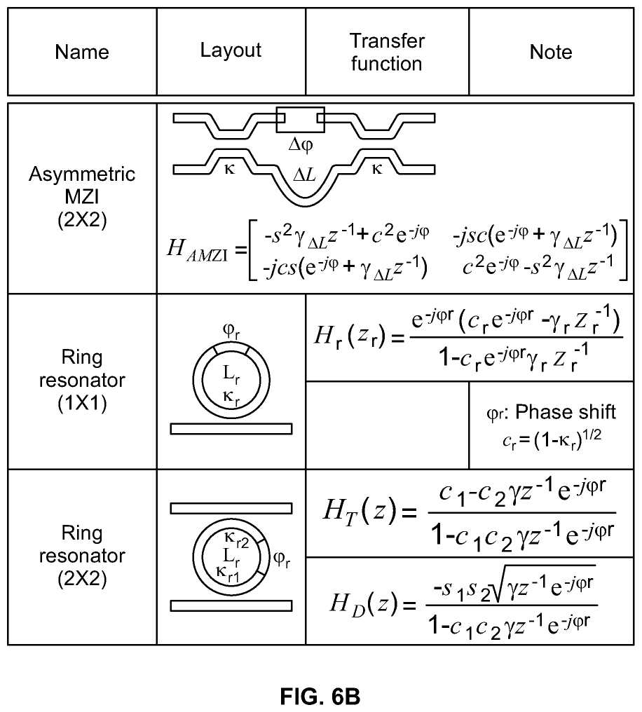

In yet other embodiments, the present invention may be used to form integrated “Quantum Circuits” by assembling devices based on the coupling of electron waves between atomic chain structures. For example, linear, ring, and other chain structures form the basic building blocks of quantum circuits as shown in FIGS. 6A and 6B. As shown, structures that may be created include waveguides, tuning elements, separated waveguides, directional couplers, differential delays, symmetric MZI, asymmetric MZI, and ring resonators.

In other embodiments, the present invention provides a semiconductor device comprised of one or more one-dimensional chains of atoms, the atoms form strong covalent bonds with no dangling bonds except at both ends of the chain, and the chains are bonded together through van der Waals force in an ordered nature to form a single crystal. The device may have a helical structure of atomic chains that require electrons to twist as they travel along the chain to produce unique magneto transport signatures, strongly affect electron spin states in the chains, and generate topological end modes. In yet other embodiments, only one direction is allowed by the helicity of the chain which will generate a magnetic field along the chain that creates a unique type of spin-orbit interaction. In other embodiments, quantum dots may be defined within the chain to create single photon sources and detectors, as well as electron spin qubits that may have enhanced coherence by engineering the nuclear isotopes of Se and Te atoms forming the chain. In other aspects, an external electrical field may be used to form a PN junction along the chain, so that the structure may be configured as a light emitting diode.

In other embodiments, the present invention provides a method wherein the atomic chain is transferred to a SiO2 substrate followed by depositing dielectric material and a metal contact to form a MOSFET. In other applications, a single chain with two electrodes may be configured as a photoconductor by choosing different metals. The structure may also work as a Schottky diode for photodetection.

In still further embodiments, the present invention provides a semiconductor device comprised of one or more one-dimensional chains of atoms, the atoms form strong covalent bonds with no dangling bonds except at both ends of the chain and the chains are bonded together through van der Waals force in an ordered nature to form regular integrated circuits as well as quantum integrated circuits by placing chains in close proximity to qubits, quantum sensors, and quantum nanophotonic devices.

In other embodiments, the chains of the semiconductor device have no dangling bonds except at both ends of the chain and the chains are bonded together through van der Waals force in an ordered nature to form a sensor. The chains may also be used to sensors for gasses, chemicals, temperature, pressure, and biomolecules (DNA, viruses, proteins). In other aspects, the atomic chains replace nanowires as sensors because of a 100× larger surface to volume ratio. The chains may also be used as pressure sensors as a result of having spiral structures and highly flexible mechanical properties.

While the foregoing written description enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above described embodiments, methods, and examples, but by all embodiments and methods within the scope and spirit of the disclosure.

1. (canceled)

2. (canceled)

3. (canceled)

4. (canceled)

5. A method of creating an atomic chain comprising the steps of:
providing an indexed substrate, said substrate including a plurality of steps having peaks, valleys and terrace edges; and
using said substrate as a template to collect and guide the alignment of the atoms received by said substrate into atomic chains.

6. The method of claim 5 wherein chains will form along said valleys as it will take more energy to form the bond laterally across said valleys than said peaks.

7. The method of claim 5 wherein atoms collect at said terrace edges.

8. The method of claim 5 wherein molecular beam epitaxy (MBE) is used to grow said atomic chains.

9. The method of claim 5 wherein Se is used to grow said chains.

10. The method of claim 5 wherein Te is used to grow said chains.

11. The method of claim 5 wherein SeTe is used to grow said chains.

12. The method of claim 5 wherein the spacing of said chains is tuned by growing said chains on different high index or cut substrates.

13. The method of claim 5 wherein said substrate is a semiconductor, GaAs surface, quartz or sapphire.

14. The method of claim 5 wherein atoms are transferred to a SiO2 substrate followed by depositing dielectric material and metal contacts to form a MOSFET.

15. The method of claim 5 wherein a single chain with two electrodes that works as a photoconductor is constructed by choosing different metals.

16. The method of claim 5 wherein an external electrical field is used to form a PN junction along the chain, so that the structure may be configured as a light emitting diode.

17. The method of claim 5 wherein said chains have spiral structures and mechanical properties which are used as pressure sensors.

18. The method of claim 5 further including the step of including an impurity atom in said chain, said impurity atom is used to connect a plurality of chains to said impurity atom.

19. The method of claim 5 further including the step of including dangling bonds at the end of said chains and bending said ends towards one another until said ends connect to form a ring structure.

20. The method of claim 5 wherein said chains are one-dimensional chains of atoms, the atoms form strong covalent bonds with no dangling bonds except at both ends of the chain and the chains are bonded together through van der Waals force to form regular integrated circuits and quantum integrated circuits.

21. The method of claim 5 wherein said chains host quantum dots functioning as single photon sources and detectors and as electron spin qubits.
